(19) United States
(12) Patent Application Publication
(10) Pub. No.: US 2003/0218229 A1
(43) Pub. Date: Nov. 27, 2003

(54) Photosensitive semiconductor diode device with passive matching circuit

(76) Inventors: Guido Janssen, Weeze (DE); Ralf M. Bertenburg, Tonisvorst (DE); Michael Agethen, Bielefeld (DE); Dietmar Keiper, Oberhausen (DE); Andreas Brennemann, Duisburg (DE); Peter Velling, Oberhausen (DE)

Correspondence Address: Robert V. Vickers, Fay, Sharpe, Fagan, Minnich & McKee, LLP, 7th Floor, 1100 Superior Avenue, Cleveland, OH, 44114-2579, US

(21) Appl. No.: 10/408,974

(22) Filed: Apr. 8, 2003

(30) Foreign Application Priority Data
Apr. 8, 2002 (DE) 102 15 414.7

(51) Int. Cl. H01L 21/00; H01L 31/075

(52) U.S. Cl. 257/458; 438/48; 257/433

(57) ABSTRACT

In a photosensitive semiconductor diode device (1), in particular, a PIN diode device (2) for converting optical signals into electronic signals, the semiconductor diode is provided with a lead for contacting the doped regions and for electroconductively connecting them to a following circuit (11), e.g., an electronic amplifier. To realize a matching between the semiconductor diode and the following circuit that is effective over a wide bandwidth by means of a passive matching circuit (10), the lead contains the matching circuit such that lead (4, 5) is constructed on at least part of its length (L) as a coplanar line or a microstrip line such that conductor width (S) and/or conductor spacing width (gap width W) varies along its length area (L) of the lead, with the characteristic impedance of this lead varying along the corresponding part of the line. A very high operating frequency and a low signal attenuation are thereby achieved, among other things.

The invention pertains to a photosensitive semiconductor diode device with a passive matching circuit with the characteristics of the preamble of claim 1, as well as to a manufacturing method with the characteristics of the preamble of claim 11.

Accordingly, the invention pertains to a photosensitive semiconductor diode device (photodiode) in which the photosensitive semiconductor diode is electroconductively connected via a lead to a following circuit such as an electronic amplifier, wherein a passive matching circuit improves the transfer of power between the photosensitive semiconductor diode and the following circuit.

### BACKGROUND OF INVENTION

Such photosensitive semiconductor diode devices (photodiodes) serve as optical receivers, which receive light, convert it into an electronic signal, and, optionally, amplify it. They are known in the form, for instance, of PN junctions that consist of a p-type and an n-type region. A common application in this regard exists in the form of a PIN diode device, which converts incident light (back) into an electronic signal at the end of an optical transmission path. Such a PIN diode is a photodiode operated in the reverse direction, in which an intrinsic layer for conversion of incident light into photocurrent is inserted between a p-type and an n-type region. The intrinsic layer is an intrinsically conductive, undoped semiconductor layer or a semiconductor layer that is comparatively weakly doped in relation to the p- or n-type regions. The applied blocking voltage falls across the intrinsic region (I) and generates a constant electric field there. A light quantum from the incident light that is absorbed in the I region generates an electron/hole pair there. That is to say, the internal photoelectric effect is exploited. For an appropriately high blocking voltage, the I region is practically free of charge carriers; newly formed electron/hole pairs are drawn out at maximal drift velocity.

Such PIN diodes are used as a photosensitive component on the receiver side for digital information transmission at high transmission rates. In this form, the PIN diode corresponds in essence to an ideal photocurrent source with a parallel-connected capacitor, which corresponds in electronic terms to a very high impedance. Ordinary input impedances of PIN diodes lie in the range of several 100 Ω. The PIN diode is usually connected on the output side to an electronic amplifier (the characteristic impedance of a power amplifier is, for instance, 50 Ω) to amplify the weak input signal and render it usable for following circuitry. Thus, following circuits no longer have any influence on the currents and voltage in the PIN diode and obtain a defined input signal. There still remains the problem, however, that the PIN diode and the amplifier input are not matched, i.e., signal power for amplification is lost because the electronic transmission bandwidth is reduced.

A customary means to solve this problem is a passive matching circuit that is inserted between PIN diode and amplifier to increase power transfer. This can be done by means of external modules via circuit housings with screw terminals, but this causes problems at high transmission rates, since the interface module has parasitic effects that cover up the actual effect. Another possibility for matching is to insert inductors into the lead between the photosensitive semiconductor diode device and the following circuit. In the ideal case, these permit a complex-conjugated matching of the complex output impedance of the PIN diode to the input impedance of the amplifier. However, this type of matching can only be achieved over a narrow frequency band.

### SUMMARY OF THE INVENTION

Proceeding from this, the invention is based on the problem of implementing by simple means a matching circuit between the photosensitive semiconductor diode and the following circuit that is effective over a broad bandwidth for photosensitive semiconductor diodes of this generic type.

This problem is solved by a photosensitive semiconductor diode device with the characteristics of claim 1. According to the latter, the invention is based on the fundamental idea of constructing at least a partial length of the lead between the photosensitive semiconductor diode and the following circuit, such as an amplifier, as a matching circuit such that this part of the line has a characteristic impedance that varies over its length. Concretely, the invention provides in this regard the use of either a coplanar line or a microstrip line with a conductor width and/or conductor spacing varying over its length, so that the characteristic impedance varies along this part of the line. If a coplanar line is used for this purpose, it is usually a planar line on a substrate support with a central conductor and two return lines arranged coplanar thereto and separated from the central line by spacing gaps.

The characteristic impedance of such a matching circuit is essentially not influenced by the thickness of the substrate, but only by the ratio of central conductor width S to gap width W. For the case when this is applied to a connection of a photosensitive PIN diode to a following circuit such as an electronic amplifier, this ratio increases with increasing distance from the PIN diode. This has the special advantage that, at the end of the respective length L of the lead section serving as the matching circuit, the conductor trace widths are sufficient to create an electrically conductive connection to ordinary electronic conductors by means of an ordinary bonding method (hybrid construction).

It is understood that the design of the widths of the central conductor and of the gaps allows nearly unlimited range for variations. In that way, the characteristic impedance of this lead can be varied in the most differentiated way, continuously, for instance, when the ratio W: S varies along the gap length L.

The length L of the lead part designed according to the invention and the variation of the characteristic impedance can be varied according to the requirements of the photosensitive semiconductor diode, such as a PIN diode, and of the following circuit, such as an amplifier circuit. In particular, the characteristic impedance can begin in the area of electronic connection (bonding area) with a characteristic impedance matched to the following circuit at 50 Ω and can increase towards the PIN diode to, for instance, several 100 Ω.

It was found that the impedance matching improves with a larger ratio of characteristic impedances at the beginning and end of the lead part designed according to the invention and that a higher inductive reactance can be achieved by increasing the gap length L.

The advantages of the solution according to the invention are among others that the matching circuit between, for instance, a PIN diode and an electronic amplifier is independent of substrate thickness. In particular, the matching circuit according to the invention functions even works at very high operating frequencies, for instance, above 100 GHz. Moreover, no parasitic effects occuns such as caused by the well-known spiral inductances. Only a slight attenuation of the electronic signal is produced.

The matching circuit can be connected directly to lines with an ordinary characteristic impedance of, for instance, 50 Ω, achieving a very high bandwidth, considerably higher than the bandwidth without a matching circuit. The architecture of a matching circuit according to the invention is also extremely simple, since only purely geometric structures need be created to match the magnitudes of the inductive reactance and characteristic impedance, which gives a high degree of flexibility. If coplanar lines are used for the matching circuit according to the invention, even considerably smaller dimensions than microstrip lines (with identical characteristic impedance) can be achieved. By the capability of matching to a 50 Ω characteristic impedance, ordinary power amplifiers can be directly connected to the matching circuit.

Besides the already mentioned hybrid structure, a monolithic integration of the PIN diode and matching circuit is possible and even preferred. Beyond that, a semiconductor diode that is impedance-matched according to the invention can also be a monolithically integrated component of a chip, for instance, an OEIC (optoelectronic integrated circuit).

The aforementioned components, as well as those claimed and described in the embodiments as used according to the invention are not subject to any particular exceptional conditions with respect to size, shaping, material selection and technical design, so that the selection criteria known in the field of use can be applied without restriction.

Further details, characteristics and advantages of the object of the invention can be discerned from the subordinate claims, as well as from the description below of the associated drawing, in which a preferred embodiment of the photosensitive semiconductor diode with passive matching circuit is presented for the sake of example. Shown in the drawing are:

### BRIEF DESCRIPTION OF THE DRAWINGS

FIG. 1a, a first embodiment of a PIN diode device, in which the width of the central conductor increases, the slot width decreases and the inner metallization edges of the outer ground conductors (metallizations) run in parallel;

FIG. 1b, an alternative PIN diode device, in which the width of the central conductor increases, the slot width decreases and the inner metallization edges of the outer ground conductors (metallizations) run towards one another;

FIG. 1c, a third embodiment of a PIN diode device, in which the width of the central conductor increases, the slot widths remain constant and the inner metallization edges of the outer ground conductors (metallizations) run apart from one another;

FIG. 1d, a fourth embodiment of a PIN diode device, in which the width of the central conductor increases, the slot width decreases and the inner metallization edges of the outer ground conductors (metallizations) run towards one another;

FIG. 2a, the embodiment of FIG. 1a with two sectional views A-A′ and B-B′ as a schematic diagram of the lead or contact structure in coplanar technology, in which the central conductor (as the signal conductor) and the outer conductors (ground line) lie in a single plane;

FIG. 2b, an alternative embodiment of PIN diode device as a schematic diagram of the lead or contact structure in microstrip technology, in which the signal conductor lies on the same side of the substrate as the diode and the ground conductor completely covers the rear side of the substrate, wherein the ground conductor is electroconductively connected to the PIN diode by a via hole connection, in plan view and in two sectional views C-C′ and D-D′;

FIG. 3a, a PIN diode device according to the embodiment of FIGS. 1a and 2a, in a sectional view (section along line B-B′ of FIG. 2a in greatly magnified representation);

FIG. 3b, the same PIN diode device in a top view;

FIG. 3c, the same PIN diode device with contact to a glass fiber as light source;

FIG. 4, an alternative embodiment of a PIN diode device with coplanar lead and monolithic integration of the diode with an electronic circuit, wherein both the diode and the circuit lie on the same substrate and are manufactured jointly;

FIG. 5, an alternative PIN diode device in so-called hybrid structure of diode and electronic circuit, in which the diode and the electronic circuit lie on different substrates and are electroconductively connected to one another via an external connection, such as by a bond wire; and

FIG. 6, to illustrate the effect of the matching circuit of a PIN diode device, a graphical representation of the electronic, optical and optoelectronic transmission function with and without the matching circuit according to the invention as a function of signal frequency.

### PREFERRED EMBODIMENT OF THE INVENTION

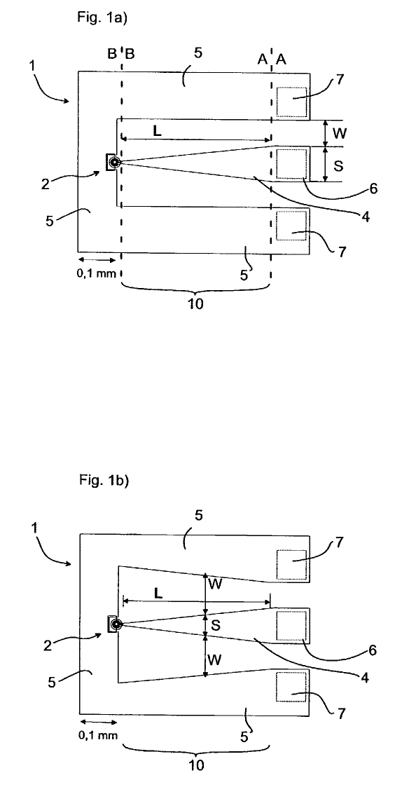

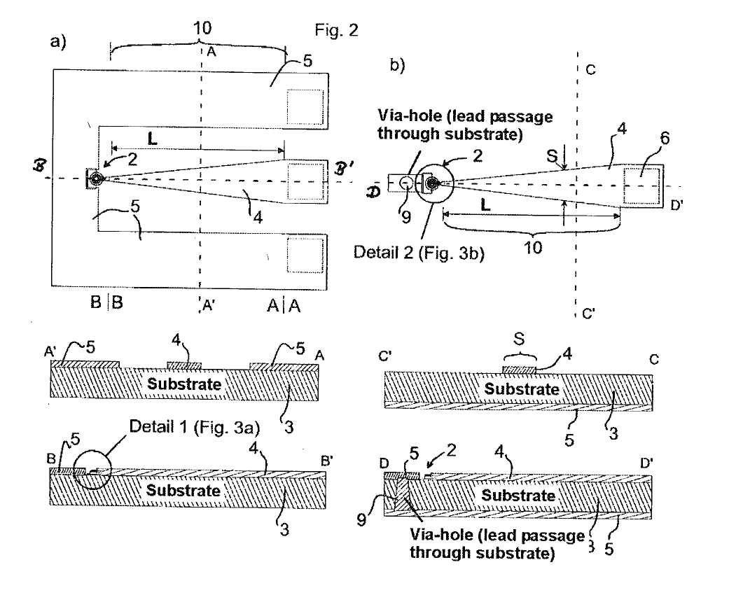

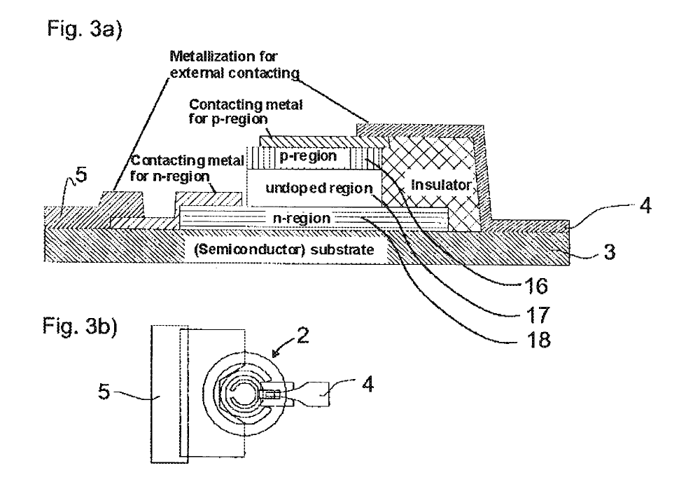

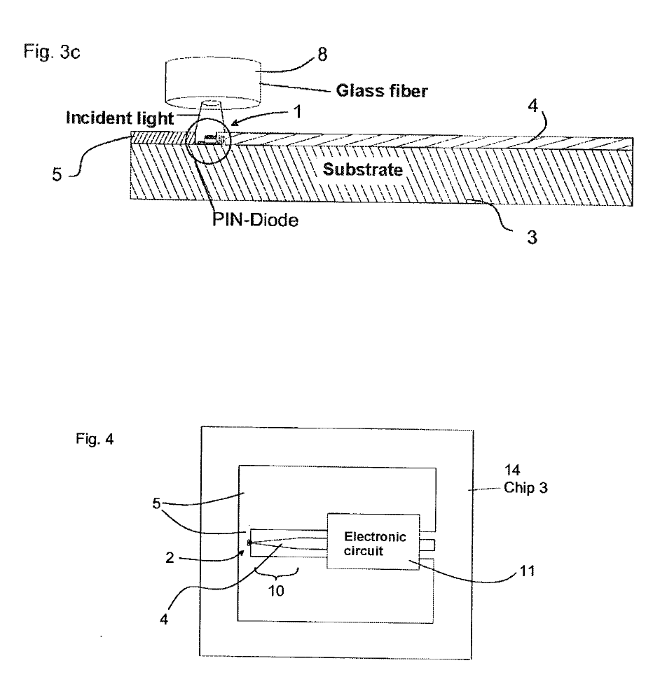

FIGS. 1a-1d yield different variants of a matching circuit 10 of a photosensitive semiconductor diode device 1. The semiconductor diode, visible in greater detail from FIG. 3a (a PIN diode 2 in the embodiment represented there), is constructed on a substrate 3 and prepared for external contacting via metallization layers 4, 5. Metallization layer 4 constitutes the central conductor visible in FIGS. 1a-1d, while metallization layer 5 constitutes the two so-called return conductors. Central line and return lines are accordingly constructed as coplanar conductors on substrate 3. They form the lead for contacting the doped regions of the semiconductor diode and for electroconductively connecting it to a downstream electronic circuit 11 as shown for the sake of example in FIGS. 4 and 5.

A passive matching circuit 10 for power transfer between the photosensitive semiconductor diode and the following circuit is provided between dash lines BB and AA in FIG. 1a. This matching circuit 10 involves part of the length of coplanar line 4, 5, wherein width S of central conductor 4 and/or gap width W between central conductor 4 and return conductors 5 change(s) along length L. Bond pads 6, 7 adjoining area L serve for additional contacting either with so-called bond wires such as those according to FIG. 5, for instance, or for contacting within an integrated circuit as shown in FIG. 4. In the latter case, the shape of these bond pads can of course adapt to the following circuitry requirements.

The PIN diode device shown in a plan view in FIG. 3b as a supplement to FIG. 3a, as well as the coupling of the PIN diode device to a light source in the form of a glass fiber cable 8 as shown in FIG. 3c, is provided for further illustration of the geometrical relationships.

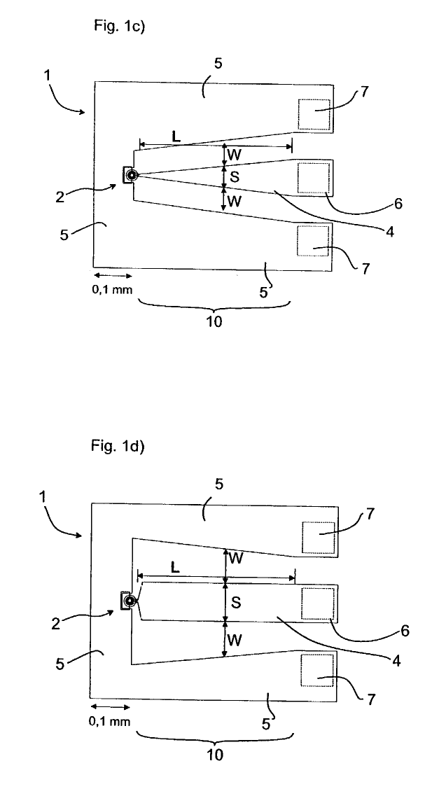

The structure of a matching circuit 10 implemented in coplanar technology is also evident from the supplementary sectional representations along lines A-A′ and B-B′ presented in FIG. 2a. As is recognizable there, the metallization layers forming central conductor 4 and return conductors 5 are formed on substrate 3, forming spacer gaps of width W, central conductor width S always varying along length L of matching circuit 10 in the embodiments of FIGS. 1a and 2a.

The PIN diode illustrated in FIG. 3a can alternatively also be provided with a matching circuit 10 in so-called microstrip technology. This is illustrated in a plan view in FIG. 2b and in section along lines C-C′ and D-D′. As is visible in FIG. 2b, the substrate is continuously metallized over the surface of its rear side with return conductor 5, which is electroconductively connected to PIN diode 2 by means of a via contact 9 through substrate 3, in this case n-region 18, as illustrated in FIG. 3a. Central conductor 4 is connected in the same manner as in the previous embodiments to p-region 16 of PIN diode 2 and extends as a microstrip on the upper side of the substrate, its width S increasing over length L of matching circuit 10 in the direction pointing away from the diode.

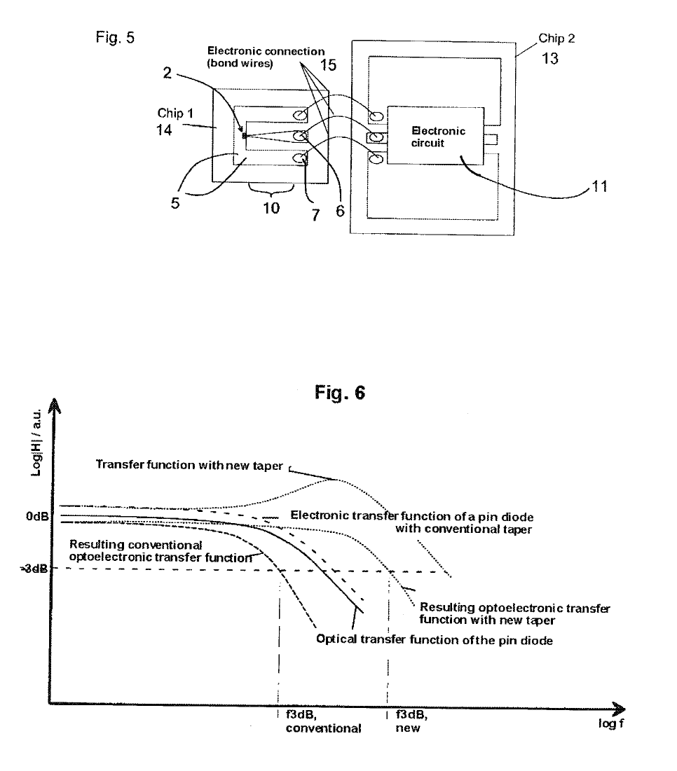

The expansion of the reasonable applicability of a semiconductor diode provided with the matching circuit of the invention to markedly higher frequencies (logarithmic scale!) is seen in FIG. 6.

LIST OF REFERENCE SYMBOLS

| | |
|---|---|
| 1 | Semiconductor diode device |
| 2 | PIN diode |
| 3 | (Semiconductor) Substrate |
| 4 | Central conductor/metallization layer |
| 5 | Return conductor/metallization layer |
| 6 | Bond pads |
| 7 | Bond pads |
| 8 | Glass fiber cable |
| 9 | Via hole contact |
| 10 | Matching circuit |
| 11 | Electronic circuit |
| 12 | Chip 1 |
| 13 | Chip 2 |
| 14 | Chip 3 |
| 15 | Bond wires |
| 16 | p-region |
| 17 | Intrinsic layer/undoped region |
| 18 | n-region |
| S | Local central conductor width |
| W | Local gap width |
| L | Length of matching circuit |

1. Photosensitive semiconductor diode device (1), consisting of
a) a photosensitive semiconductor diode (2),
b) a lead (4, 5) for contacting the doped regions of semiconductor diode (2) and for electroconductively connecting it to a following circuit (11) such as an electronic amplifier and
c) a passive matching circuit for transferring power between photosensitive semiconductor diode (2) and following circuit (11),
characterized in that,
the lead contains matching circuit (10) such that the lead is designed on at least part of its length (L) as a coplanar line or a microstrip line with conductor width (S) and/or conductor spacing width (gap width W) varying along its length (L).

2. Semiconductor diode device according to claim 1, characterized in that photosensitive semiconductor diode (2) is a PIN diode for converting optical signals into electronic signals, in which an intrinsic layer (17) as a region for converting incident light into a photocurrent is inserted between a p-type region (16) and an n-type region (18).

3. Semiconductor diode device according to claim 2, characterized in that the PIN diode is constructed as a barrier layer photodiode.

4. Semiconductor diode device according to one of the preceding claims, characterized in that the characteristic impedance of part (L) of the lead length that forms matching circuit (10) varies, in particular, increases, uniformly or nonuniformly or in steps between a connection surface (6, 7) at one end and its semiconductor diode-side other end.

5. Semiconductor diode device according to one of the preceding claims, characterized in that semiconductor diode (2) is a component of a module (housing with semiconductor diode).

6. Semiconductor diode device according to one of the preceding claims, characterized in that an amplifier (11) is monolithically integrated into semiconductor device (1).

7. Semiconductor diode device according to one of the preceding claims, characterized in that a PIN diode (2) is integrated with matching circuit (10) and downstream amplifier (11) in one module.

8. Semiconductor diode device according to one of the preceding claims, characterized in that length area (L) constituting the matching circuit of a coplanar lead consists of a central conductor (4) and return conductors (5) separated therefrom by gap (W) and running essentially parallel thereto.

9. Semiconductor diode device according to claim 8, characterized in that the ratio of central conductor width (S) to gap width (W) varies along gap length (L), in particular, facing a way from the contact zone of semiconductor diode (2).

10. Semiconductor diode device according to one of claims 1-7, characterized in that at least length area (L) of the lead that constitutes matching circuit (10) is designed as a microstrip line, wherein, on one side of a substrate (3) an electrically conductive microstrip (4) facing away from the semiconductor diode is provided with a width (S) increasing along its length and a full-surface or strip-shaped electrically conductive microstrip (5) is provided on the rear side of substrate (3).

11. Method of manufacturing a semiconductor diode device, in particular, according to one of claims 1-10, characterized in that a photosensitive semiconductor diode such as a PIN diode (2), constructed on a substrate (3), in particular, a conductive one, is contacted at one end to a metallization layer (4) which extends, facing away from the semiconductor diode, on substrate (3) over a length (L) up to a contact zone (6), and a second metallization layer (5) is placed, starting from a second contact surface of the semiconductor diode, on the same or the opposite side of the substrate, the width of at least one of the metallization layers and or the lateral spacing of the metallization layers varying along a path (L) pointing away from the semiconductor diode.
